(19) United States
(12) Patent Application Publication
(10) Pub. No.: US 2008/0124821 A1
(43) Pub. Date: May 29, 2008

(54) METHOD FOR FABRICATING A PIXEL STRUCTUR OF ORGANIC ELECTROLUMINESCENT DISPLAY

(75) Inventors: Chien-Chang Tseng, Kaohsiung County (TW); Pei-Lin Huang, Hsinchu City (TW); Chiu-Yen Su, Chiayi County (TW)

Correspondence Address: J C PATENTS, INC., 4 VENTURE, SUITE 250, IRVINE, CA, 92618, US

(73) Assignee: CHUNGHWA PICTURE TUBES, LTD., Taipei (TW)

(21) Appl. No.: 11/462,463

(22) Filed: Aug. 4, 2006

(51) Int. Cl. H01L 51/56; H01L 21/04

(52) U.S. Cl. 438/22; 438/99; 438/241; 438/482; 257/E21.04; 257/E51.019

(57) ABSTRACT

A method for fabricating a pixel structure of an OELD includes the following steps. First, a first gate, a scan line and a second gate are formed on a substrate. Next, a gate insulation layer is formed on the substrate to cover the first gate, the scan line and the second gate. Then, on the gate insulation layer, a first channel layer and a second first channel layer are formed, which are located over the first gate and the second gate, respectively. Afterwards, a first source and a first drain beside the first channel layer and a data line are formed; meanwhile, a second source and a second drain beside the second channel layer, and a cathode electrically connected to the second drain are formed. Further, an organic functional layer is formed on the cathode. Finally, an anode is formed on the organic functional layer.

### BACKGROUND OF THE INVENTION

1. Field of Invention

The present invention relates to a method for fabricating a pixel structure, and particularly to a method for fabricating a pixel structure of an organic electroluminescent display.

2. Description of the Related Art

The rapid development in the multimedia industry is largely attributed to the progress in semiconductor devices or display apparatuses. In terms of displays, a flat panel display, with such advantages as high display quality, high space utilization, low power consumption and no radiation, have played a major role on the mainstream display market. The flat panel display available currently includes a liquid crystal display (LCD), an organic electroluminescent display (OELD) and a plasma display panel (PDP) and so on. Wherein, the OELD has a great potential for development due to the overwhelming advantages of no AOV (angle of view) limitation, low production-cost, fast responding (approximately over a hundred times faster than LCD), electricity-saving, DC driving, broader operation temperature range, light-weight and downsized volume therewith. Normally, an OELD is formed by a plurality of pixel structures and each pixel structure is able to emit different color light depending on the emitting material thereof, so to achieve full colorization display. FIGS. 1A˜1G are schematic cross-sectional views showing the fabrication flowchart of an OELD pixel structure in the prior art. FIG. 2 is a circuit diagram of a conventional OELD pixel structure. Referring to FIG. 1A, an amorphous material is deposited on a substrate 100 and then a laser annealing process to the amorphous layer is performed so as to form a polysilicon material, followed by a mask process to pattern the polysilicon material to form a first polysilicon layer 110 and a second polysilicon layer 112. Next, a gate insulation layer 120 is formed over the substrate 100 to cover the first polysilicon layer 110 and the second polysilicon layer 112.

Continuing to FIGS. 1B and 2, a conductive material is deposited on the gate insulation layer 120, followed by a mask process to pattern the conductive material to form a first gate 130 and a second gate 132. Afterwards, the first gate 130 and the second gate 132 are used as masks to conduct a doping process, so as to form a first source region 110a and a first drain region 110b in the first polysilicon layer 110 beside the first gate 130 and to form a second source region 112a and a second drain region 112b in the second plysilicon layer 112 beside the second gate 132, respectively.

Further referring to FIG. 1C, a dielectric layer 140 is formed over the substrate 100 to cover the first gate 130, the second gate 132 and the gate insulation layer 120. After that, the dielectric layer 140 is patterned by using a mask process, so that a first via hole C1, a second via hole C2, a third via hole C3 and a fourth via hole C4 are formed in the dielectric layer 140 and the gate insulation layer 120. The first via hole C1 and the second via hole C2 expose the first source region 110a and the first drain region 110b, respectively, while the third via hole C3 and the fourth via hole C4 expose the second source region 112a and the second drain region 112b, respectively.

Furthermore referring to FIG. 1D, a metal material is deposited on the substrate 100 and fills in the first via hole C1, the second via hole C2, the third via hole C3 and the fourth via hole C4. Then, the metal material is patterned by using a mask process to form a first source 150, a second source 152, a first drain 154 and a second drain 156.

After that, referring to FIG. 1E, a protection layer 160 is formed on the substrate 100 to cover the dielectric layer 140, the first source 150, the second source 152, the first drain 154 and the second drain 156. Then, the protection layer 160 is patterned by using a mask process, so that a fifth via hole C5 is formed in the protection layer 160 to expose the second source 152.

After that, referring to FIG. 1F, indium tin oxide (ITO) is deposited over the substrate 100 and fills in the fifth via hole C5. Then, by using a mask process, the ITO is patterned to form an anode 170 electrically connected to the second source 152. Finally referring to FIG. 1G, an emitting layer 172 is formed over the substrate 100 to cover the anode 170by using a shadow mask process. Note that the emitting layer 172 is able to emit red light, blue light or green light depending on the selected organic emitting material. After that, a metal material is deposited on the emitting layer 172 to form a cathode 174.

In more detail, the anode 170, the emitting layer 172 and the cathode 174 form an organic electroluminescent device 180 as shown in FIG. 2. In FIG. 2, a switch transistor Ts is formed by the first gate 130, the first source 150 and the first drain 154; a driving transistor Td is formed by the second gate 132, the second source 152 and the second drain 156.

The first gate 130 of the switch transistor Ts is electrically connected to a scan line 10, which is defined in the step shown by FIG. 1B together with the first gate 130 and the second gate 132. The first source 150 of the switch transistor Ts is electrically connected to a data line 20, which is defined in the step shown by FIG. 1D together with the first source 150 and the first drain 154.

In general, there is a capacitor 30 disposed between the second gate 132 of the driving transistor Td and the first drain 154 of the driving transistor Td. Besides, the anode 170 of the organic electroluminescent device 180 is electrically connected to the source 152 of the driving transistor Td. Based on the transistor theory, once the voltage V_{gs} between gate and source of transistor is larger than the threshold voltage Vₜ, the transistor is turned on; at the beginning, that is to say the voltage V_{ds} between drain and source is not high and V_{ds}<V_{gs}-V_{t,}, the current I though organic electroluminescent device is roughly proportional to the voltage V_{ds} between drain and source and it corresponds to linear region; along with an increased running time of the organic electroluminescent device 180, the voltage between drain and source would be accordingly increased, and as V_{ds}>>V_{gs}-Vₜ, it comes to saturation region, where the current I though organic electroluminescent device is no more proportional to the voltage V_{ds} between drain and source and keeps a maximum value thereof. According to the transistor theory, the saturation equation of a transistor is expressed as follows:

I=½μC(W/L)(V_{gs}-Vₜ)²

I: current passing through organic electroluminescent device

μ: electron mobility

C: gate capacitance of unit area

W: gate width

L: effective length of gate

V_{gs}: voltage between gate and source of driving transistor

Vₜ: threshold voltage

Due to the reduced voltage between the second gate 132 and the second source 152 of the driving transistor Td, the current I of the organic electroluminescent device 180 would be accordingly reduced, which results in a lower light-emitting luminance of the organic electroluminescent device 180. Thus, the display quality of the OELD is negatively affected. In addition, note that a full colorization OELD usually employs three different organic luminescence materials for different pixel structures, wherein the different organic luminescence materials have different decay rates, which would lead display uniformity of the OELD panel to be deteriorated.

It is further noticeable that a pixel structure 200 of a conventional OELD requires seven mask processes, as shown in the above-described FIGS. 1A˜1G, to be completely fabricated, which not only consumes high fabrication cost, but also fails to effectively shorten the process time and directly effects the throughput.

### SUMMARY OF THE INVENTION

An objective of the present invention is to provide a method for fabricating pixel structures of an OELD, so for solving the problem faced by the conventional fabrication method which fails to effectively reduce the fabrication cost.

Another objective of the present invention is to provide a method for fabricating pixel structures of an OELD, so for solving the problem of the conventional OELD which demonstrates a poor display quality after long time working.

To achieve the above-described or other objects, the present invention provides a method for fabricating pixel structures of an OELD; the method includes the steps as follows. First, a first gate, a scan line electrically connected to the first gate and a second gate are formed on a substrate. Next, a gate insulation layer is formed over the substrate to cover the first gate, the scan line and the second gate. Afterwards, a first channel layer and a second channel layer are formed on the gate insulation layer and located over the first gate and the second gate, respectively. Further, a metal layer is formed over the substrate to cover the first channel layer and the second channel layer. Furthermore, the metal layer is patterned to form a first source and a first drain beside the first channel layer and a data line electrically connected to the first source and to form a second source and a second drain beside the second channel layer and a cathode electrically connected to the second drain. After that, an organic functional layer is formed on the cathode. Finally, an anode is formed on the organic functional layer.

In an embodiment of the present invention, the above-described method for fabricating pixel structures of an OELD further includes forming a capacitor, wherein an end of the capacitor is electrically connected to the second gate and the first drain, while another end thereof is electrically connected to the second source.

In an embodiment of the present invention, the above-described method for fabricating pixel structures of an OELD further includes forming a first ohmic contact layer between the first channel layer and both of the first source and the first drain.

In an embodiment of the present invention, the above-described method for fabricating pixel structures of an OELD further includes forming a second ohmic contact layer between the second channel layer and both of the second source and the second drain.

In an embodiment of the present invention, the material of the above-described first channel layer and second channel layer includes amorphous silicon (a-Si).

In an embodiment of the present invention, the material of the above-described first channel layer and second channel layer can include organic semiconductor material.

In an embodiment of the present invention, the material of the above-described cathode can include aluminum, chromium, silver, aluminum alloy, chromium alloy or silver alloy.

In an embodiment of the present invention, the material of the above-described anode can include indium tin oxide (ITO), indium zinc oxide (IZO) or aluminum zinc oxide (AZO).

In an embodiment of the present invention, prior to forming the organic functional layer on the cathode, the above-described method for fabricating pixel structures of an OELD further includes forming an insulation layer over the substrate to expose the cathode.

In an embodiment of the present invention, after forming the cathode, the above-described method for fabricating pixel structures of an OELD further includes performing a plasma processing on the surface of the cathode.

In an embodiment of the present invention, the gas used by the above-described plasma processing can include hydrogen gas, oxygen gas or nitrogen gas.

The present invention provides a method for fabricating pixel structures of an OELD, the method includes the steps as follows. First, a first polysilicon layer and a second polysilicon layer are formed on a substrate. Next, a gate insulation layer is formed over the substrate to cover the first polysilicon layer and the second polysilicon layer. Afterwards, a first gate, a scan line electrically connected to the first gate and a second gate are formed on the gate insulation layer, respectively, wherein the first gate and the second gate are located over the first polysilicon layer and the second polysilicon layer, respectively. Further, a first source region and a first drain region are formed in the first polysilicon layer beside the first gate, while a second source region and a second drain region are formed in the second polysilicon layer beside the second gate. Furthermore, a dielectric layer is formed over the substrate to cover the first gate and the second gate. Then, a first via hole, a second via hole, a third via hole and a fourth via hole are formed in the dielectric layer and the gate insulation layer, wherein the first via hole and the second via hole expose the first source region and the first drain region, respectively, while the third via hole and the fourth via hole expose the second source region and the second drain region, respectively. After that, a metal layer is formed on the dielectric layer to fill in the first via hole, the second via hole, the third via hole and the fourth via hole. After that, the metal layer is patterned to form a first source, a first drain and a data line electrically connected to the first source and meanwhile to form a second source, a second drain and a cathode electrically connected to the second drain. After that, a protection layer is formed over the substrate to cover the data line, the scan line, the first source, the first drain, the second source and the second drain. After that, an organic functional layer is formed on the cathode. Finally, an anode is formed on the organic functional layer.

In an embodiment of the present invention, the above-described method for fabricating pixel structures of an OELD further includes forming a capacitor, wherein an end of the capacitor is electrically connected to the second gate and the first drain, while another end thereof is electrically connected to the second source.

In an embodiment of the present invention, the material of the above-described cathode can include aluminum, chromium, silver, aluminum alloy, chromium alloy or silver alloy.

In an embodiment of the present invention, the material of the above-described anode can include indium tin oxide (ITO), indium zinc oxide (IZO) or aluminum zinc oxide (AZO).

In an embodiment of the present invention, prior to forming the organic functional layer on the cathode, the above-described method for fabricating pixel structures of an OELD further includes forming an insulation layer over the substrate to expose the cathode.

In an embodiment of the present invention, after forming the cathode, the above-described method for fabricating pixel structures of an OELD further includes performing a plasma processing on the surface of the cathode.

In an embodiment of the present invention, the gas used by the above-described plasma processing can include hydrogen gas, oxygen gas or nitrogen gas.

In the method for fabricating pixel structures of an OELD provided by the present invention, since the cathode is formed with the sources and the drains together, so that in comparison with the conventional method, the method for fabricating pixel structures of an OELD provided by the present invention is able to reduce a mask process, which economizes both the fabrication cost and the process time, and further effectively advances the throughput.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve for explaining the principles of the invention.

FIGS. 1A˜1G are schematic cross-sectional views showing the fabrication flowchart of an OELD pixel structure in the prior art.

FIG. 2 is a circuit diagram of a conventional OELD pixel structure.

FIGS. 3A-3F are schematic cross-sectional views showing the fabrication flowchart of an OELD pixel structure according to the first embodiment of the present invention.

FIG. 4 is a circuit diagram of an OELD pixel structure according to the first embodiment of the present invention.

FIGS. 5A-5G are schematic cross-sectional views showing the fabrication flowchart of an OELD pixel structure according to the second embodiment of the present invention.

FIG. 6 is a circuit diagram of an OELD pixel structure according to the second embodiment of the present invention.

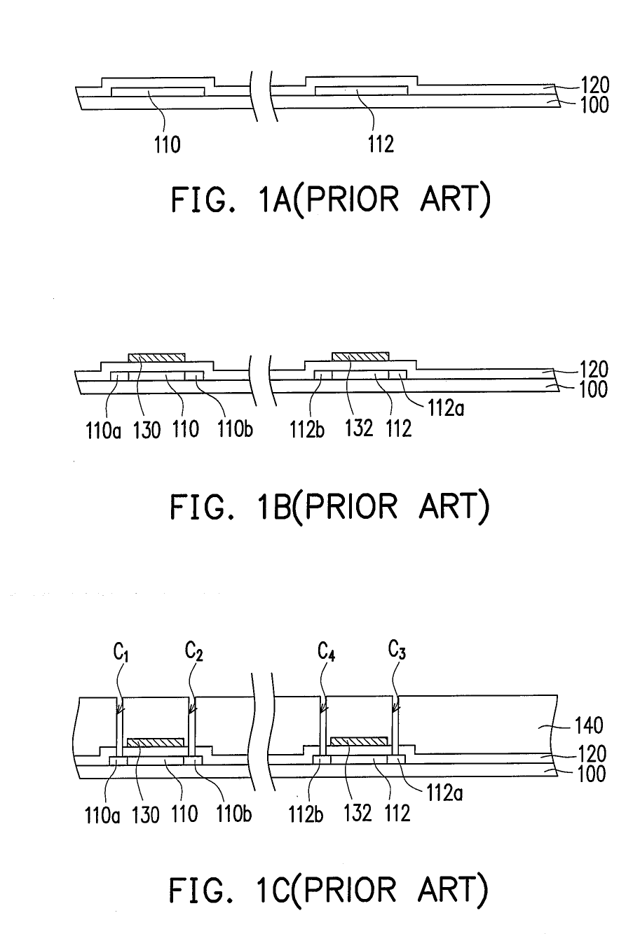

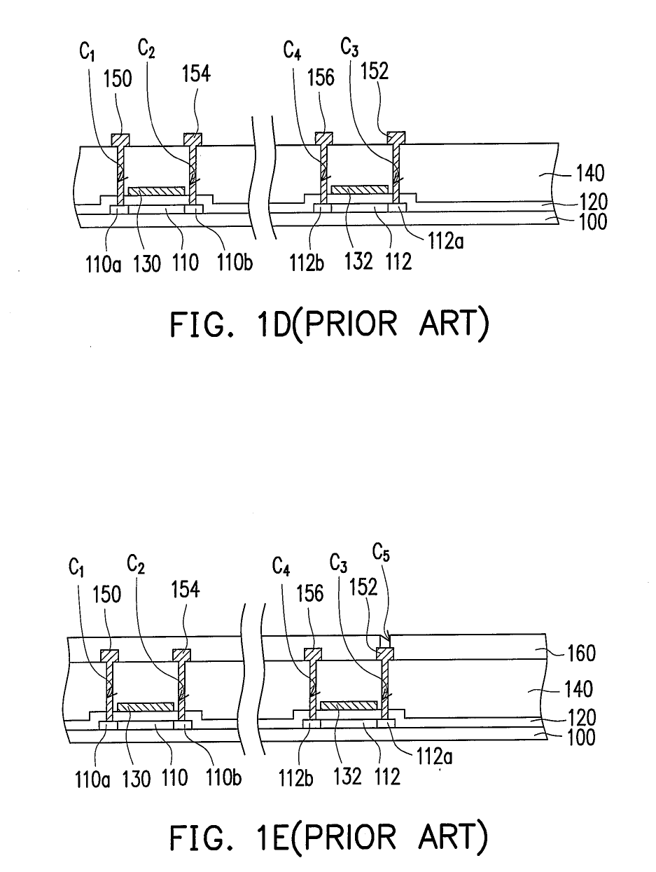

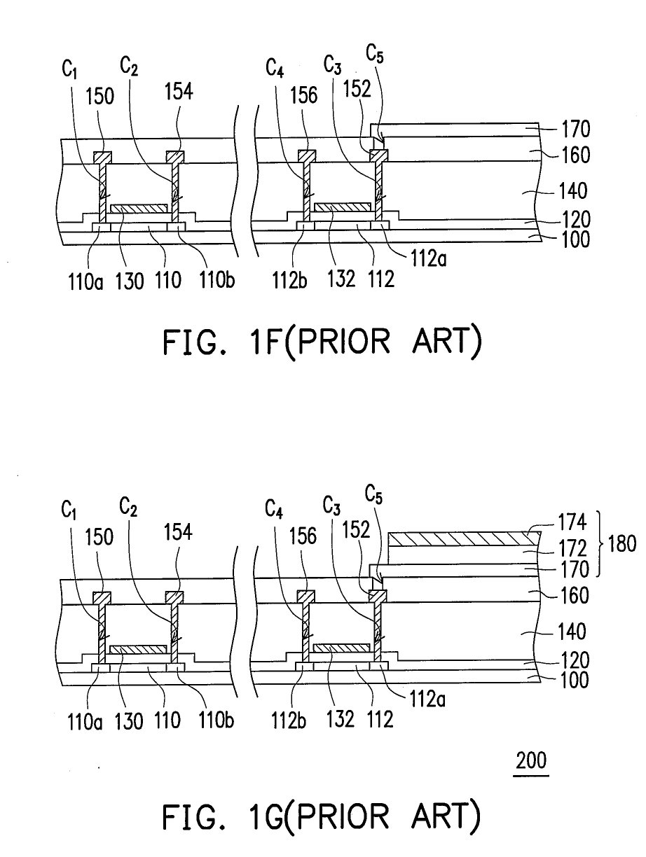

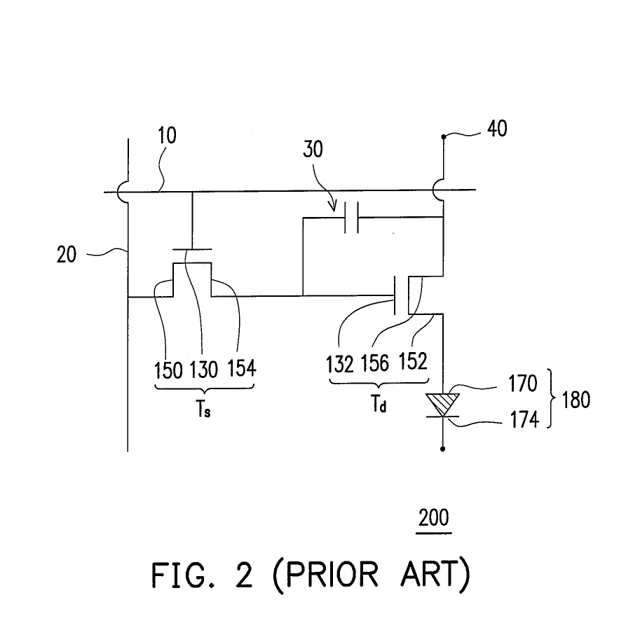

### DESCRIPTION OF THE EMBODIMENTS

### The First Embodiment

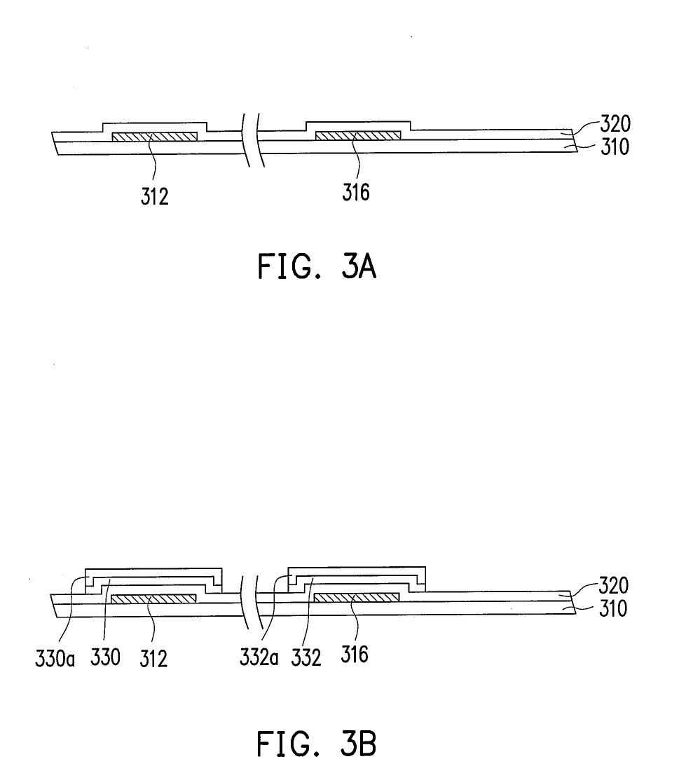

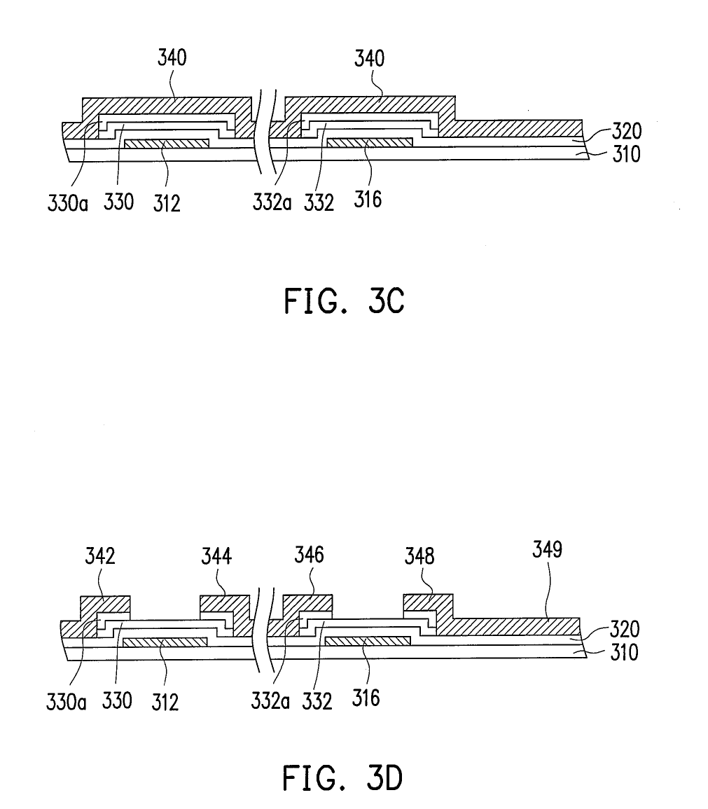

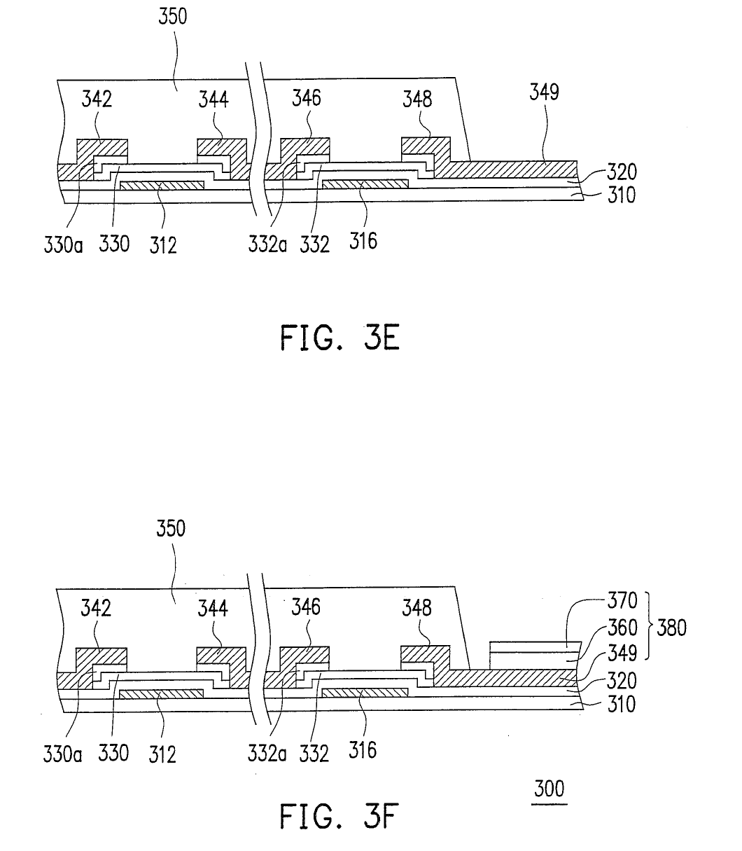

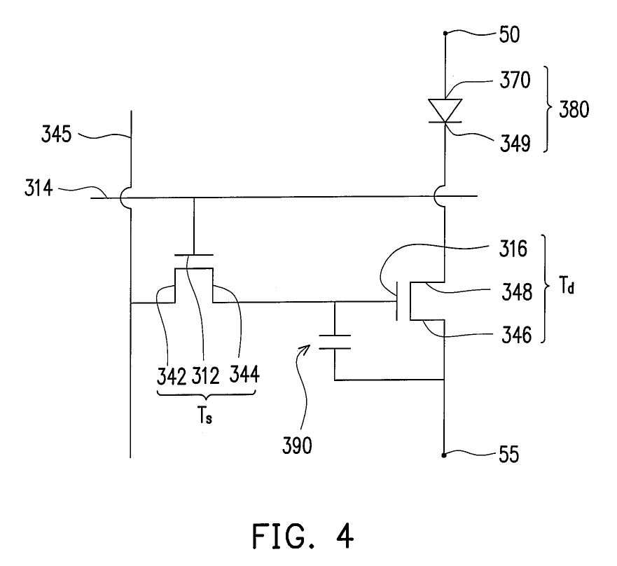

FIGS. 3A-3F are schematic cross-sectional views showing the fabrication flowchart of an OELD pixel structure according to the first embodiment of the present invention, while FIG. 4 is a circuit diagram of an OELD pixel structure according to the first embodiment of the present invention. Referring to FIG. 3A and FIG. 4 first, a first gate 312, a scan line 314 electrically connected to the first gate 312 and a second gate 316 are formed on a substrate 310.

In more detail, the first gate 312, the scan line 314 and the second gate 316 are formed, for example, by using a physical vapor deposition process (PVD) to deposit a metal material on the substrate 310, followed by using a mask process to pattern the metal material to complete the fabrications of the first gate 312, the scan line 314 and the second gate 316. The above-mentioned metal material can be a low-resistance material, such as aluminum, gold, copper, molybdenum, chromium, titanium, aluminum alloy, aluminum-magnesium alloy, molybdenum alloy or copper alloy. Next, a gate insulation layer 320 is formed over the substrate 310 to cover the first gate 312, the scan line 314 and the second gate 316. The material of the gate insulation layer 320 can be silicon nitride or silicon oxide formed by using a reaction gas of tetraethyl orthosilicate (TEOS, Si(OC2H5)4).

Then referring to FIG. 3B, a first channel layer 330 and a second channel layer 332 are formed on the gate insulation layer 320 and located over the first gate 312 and the second gate 316, respectively. The above-mentioned first channel layer 330 and second channel layer 332 can be formed by using, for example, chemical vapor deposition process (CVD) to deposit amorphous silicon (a-Si) or organic semiconductor material on the substrate 310, followed by a mask process to pattern the a-Si or the organic semiconductor material deposited on the substrate 310 to complete the fabrications of the first channel layer 330 and the second channel layer 332.

To reduce the contact impedance between the metal material and both the first channel layer 330 and the second channel layer 332, a first ohmic contact layer 330a and a second ohmic contact layer 332a are formed on the first channel layer 330 and the second channel layer 332, respectively.

Further referring to FIG. 3C, a metal layer 340 is formed over the substrate 310 to cover the first ohmic contact layer 330a, the second ohmic contact layer 332a and the gate insulation layer 320, wherein the material of the metal layer 340 is, for example, aluminum, chromium, silver, aluminum alloy or aluminum-magnesium alloy, chromium alloy or silver alloy.

Furthermore referring to FIG. 3D, the metal layer 340 is patterned by using a mask process to form a first source 342 and a first drain 344 beside the first channel layer 330 and a data line 345 electrically connected to the first source 342 (referring to FIG. 4) and to form a second source 346 and a second drain 348 beside the second channel layer 332 and a cathode 349 electrically connected to the second drain 348. After that, the partial first ohmic contact layer 330a exposed by the first source 342 and the first drain 344 and the partial second ohmic contact layer 332a exposed by the second source 346 and the second drain 348 are removed.

According to the embodiment of the present invention, after forming the cathode 349, a plasma processing can be further performed on the surface of the cathode 349 to remove the oxide on the surface of the cathode 349 and to reduce the roughness of the surface of the cathode 349. Besides, the gas used by the above-described plasma processing can include hydrogen gas, oxygen gas or nitrogen gas.

Continuing to FIG. 3E, after the step shown in FIG. 3D in an embodiment, an insulation layer 350 is formed over the substrate 310 to expose the cathode 349. The method to form the insulation layer 350 is, for example, to deposit silicon oxide, silicon nitride or silicon oxynitride to cover the first source 342, the first drain 344, the data line 345, the second source 346, the second drain 348 and the cathode 349. Then, the deposited material is patterned by using a mask process to expose the cathode 349.

Continuing to FIG. 3F, an organic functional layer 360 is formed on the cathode 349. In an embodiment, the method to form the organic functional layer 360 can be, for example, to form the organic functional layer 360 on the cathode 349 by a shadow mask process. Note that the organic functional layer 360 mainly includes an organic emitting layer. In other embodiments however, the organic functional layer 360 can further include an electron transport layer, an electron injection layer, a hole transport layer and a hole injection layer as well.

After that, an anode 370 is formed on the organic functional layer 360, and the material of the anode 370 is, for example, indium tin oxide (ITO), indium zinc oxide (IZO) or aluminum zinc oxide (AZO). The anode 370 can have a common electrode structure.

In the above-described method for fabricating pixel structures of an OELD, since the cathode 349 is defined simultaneously with forming the first source 342, the first drain 344, the second source 346 and the second drain 348, so that in comparison with the conventional method, the method for fabricating pixel structures of an OELD provided by the present invention is able to reduce a mask process, which economizes both the fabrication cost and the process time, and further effectively advances the throughput.

The pixel structure formed by the above-described method is shown in FIG. 3F and FIG. 4, where the first gate 312, the first source 342, the first drain 344 constitute a switch transistor Ts as shown in FIG. 4. The first gate 312 of the switch transistor Ts is electrically connected to the scan line 314, while the first source 342 of the switch transistor Ts is electrically connected to the data line 345.

The second gate 316, second source 346 and the second drain 348 in the present invention constitute a driving transistor Td as shown in FIG. 4. The second gate 316 of the driving transistor Td is electrically connected to the first drain 344. In an embodiment, a capacitor 390 can be further formed in the pixel structure, wherein an end of the capacitor 390 is electrically connected to the first drain 344 and the second gate 316, while another end thereof is electrically connected to the second source 346. One terminal of the capacitor 390 and the second source 346 are electrically connected to a reference voltage 55.

In addition, the cathode 349, the organic functional layer 360 and the anode 370 constitute an organic electroluminescent device 380 in the present invention. In particular, the cathode 349 of the organic electroluminescent device 380 is electrically connected to the drain 348 of the driving transistor Td, while the anode 370 is electrically connected to a power supply 50. In this way, the organic electroluminescent device 380 is not affected by a variation of the voltage V_{gs} between gate and source of the driving transistor Td, which is able to solve the problem of reduced light-emitting luminance caused by a dropped voltage V_{gs} faced by the conventional organic electroluminescent device. Thus, the pixel structure design of the present invention enables an OELD to have more stable display quality. On the other hand, when the pixel structure 300 of the present invention is used for displaying full colorization frames, a good color display quality is also guarantied.

### The Second Embodiment

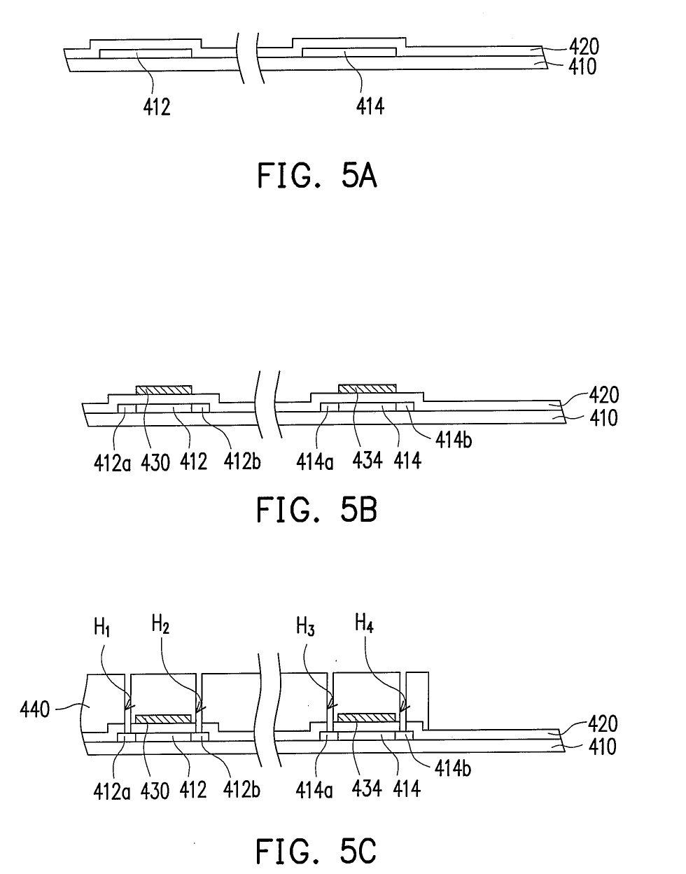

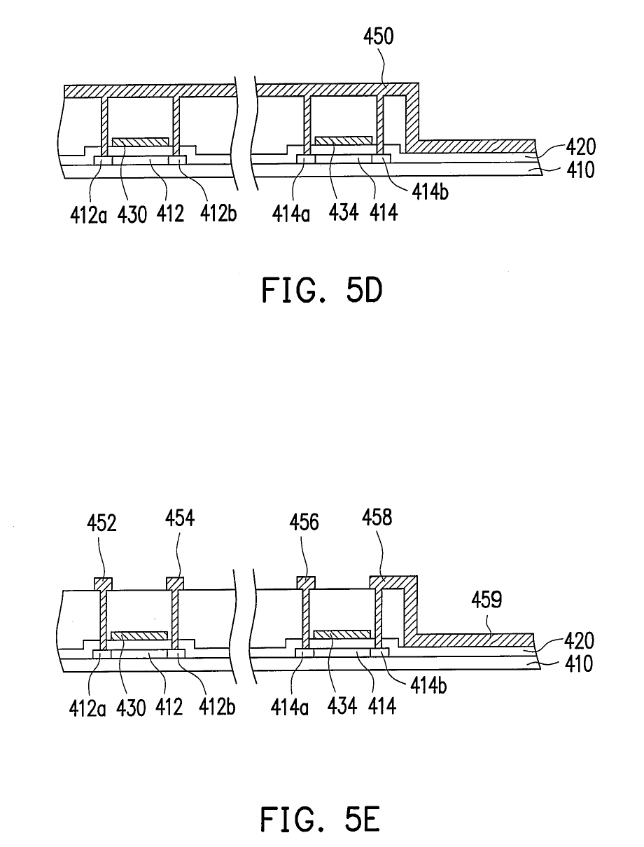

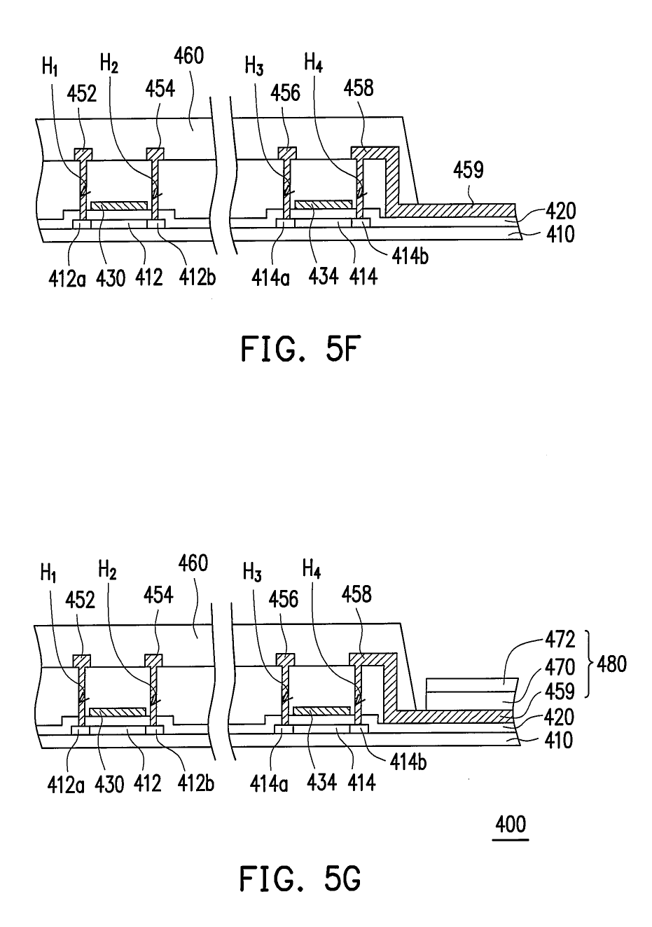

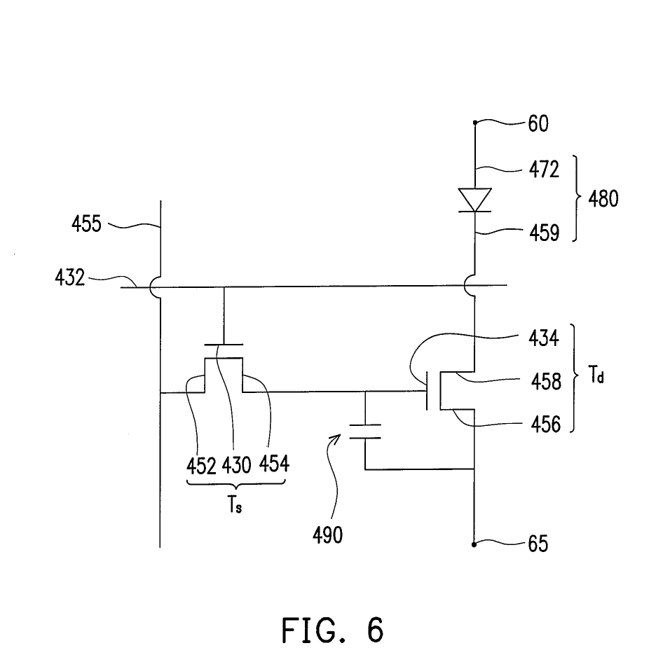

Unlike the first embodiment where the switch transistor and the driving transistor of the pixel structure use a-Si or organic semiconductor material as the channel material thereof, the pixel structure of the second embodiment employs low temperature poly silicon thin film transistors (LTPS TFTs) as the switch transistor and the driving transistor thereof. FIGS. 5A-5G are schematic cross-sectional views showing the fabrication flowchart of an OELD pixel structure according to the second embodiment of the present invention. FIG. 6 is a circuit diagram of an OELD pixel structure according to the second embodiment of the present invention. First referring to FIG. 5A, a first polysilicon layer 412 and a second polysilicon layer 414 are formed on a substrate 410. In more detail, the first polysilicon layer 412 and the second polysilicon layer 414 are made by using, for example, CVD to deposit a-Si material on the substrate 410, followed by a laser annealing to convert the a-Si material into polysilicon material. Then, a mask process is used to pattern the polysilicon material, thus, the first polysilicon layer 412 and the second polysilicon layer 414 are completely fabricated. Afterwards, a gate insulation layer 420 is formed over the substrate 410 to cover the first polysilicon layer 412 and the second polysilicon layer 414.

Next referring to FIG. 5B and FIG. 6, a first gate 430, a scan line 432 electrically connected to the first gate 430 (referring to FIG. 6) and a second gate 434 are formed on the gate insulation layer 420, respectively. The first gate 430 and the second gate 434 are located over the first polysilicon layer 412 and the second polysilicon layer 414, respectively.

In more detail, the first gate 430, the scan line 432 and the second gate 434 are fabricated by using, for example, PVD to deposit metal material on the substrate 410, followed by a mask process to pattern the metal material to complete the fabrications of the first gate 430, the scan line 432 and the second gate 434. The above-mentioned metal material can be a low-resistance material, such as aluminum, gold, copper, molybdenum, chromium, titanium, aluminum alloy, aluminum-magnesium alloy, molybdenum alloy or copper alloy.

Afterwards, a doping process is performed by using the first gate 430 and the second gate 434 as masks to form a first source region 412a and a first drain region 412b in the first polysilicon layer 412 beside the first gate 430 and form a second source region 414a and a second drain region 414b in the second polysilicon layer 414 beside the second gate 434.

Further referring to FIG. 5C, a dielectric layer 440 is formed over the substrate 410 to cover the first gate 430, the second gate 434 and the gate insulation layer 420. Then, a first via hole H1, a second via hole H2, a third via hole H3 and a fourth via hole H4 are formed in the dielectric layer 440 and the gate insulation layer 420. The first via hole H1 and the second via hole H2 expose the first source region 412a and the first drain region 412b, respectively; the third via hole H3 and the fourth via hole H4 expose the second source region 414a and the second drain region 414b, respectively.

The method to form the dielectric layer 440 can be that depositing silicon oxide, silicon nitride or silicon oxynitride over the substrate 410 to cover the first gate 430 and the second gate 434, followed by a mask process to pattern the deposited silicon oxide, silicon nitride or silicon oxynitride. Thus, the dielectric layer 440, the first via hole H1, the second via hole H2, the third via hole H3 and the fourth via hole H4 are formed.

Furthermore referring to FIG. 5D, a metal layer 450 is formed on the dielectric layer 440 to fill in the first via hole H1, the second via hole H2, the third via hole H3 and the fourth via hole H4, respectively. After that, referring to FIG. 5E, a mask process is used to pattern the metal layer 450. Thus, a first source 452, a first drain 454 and a data line 455 (referring to FIG. 6) electrically connected to the first source 452 are formed; meantime, a second source 456, a second drain 458 and a cathode 459 electrically connected to the second drain 458 are formed as well.

In an embodiment, after forming the cathode 459, the method further includes performing a plasma processing on the surface of the cathode 459 to remove the oxide on the surface of the cathode 459 and to reduce the roughness of the surface of the cathode 459. Besides, the gas used by the plasma processing can include hydrogen gas, oxygen gas or nitrogen gas.

According to an embodiment of the present invention, after the step shown in FIG. 5E, the method further includes a step shown in FIG. 5F, wherein an insulation layer 460 is formed over the substrate 410 and the insulation layer 460 would expose the cathode 459. The method to form the insulation layer 460 can be, for example, depositing silicon oxide, silicon nitride or silicon oxynitride to cover the first source 452, the first drain 454, the data line 455, the second source 456, the second drain 458 and the cathode 459, followed by a mask process to pattern the deposited material to expose the cathode 459.

After that, referring to FIG. 5G, an organic emitting layer 470 is formed on the cathode 459 and an anode 472 is formed on the organic emitting layer 470. The method for forming the organic emitting layer 470 and the anode 472 is same as or similar to the method described in the first embodiment.

Similarly, in the above-described fabrication flowchart of the OELD pixel structure 400, the cathode 459 is defined at the same time as the first source 452 and the first drain 454, the second source 456 and the second drain 458 are defined. Therefore, in comparison with the conventional method, the fabrication method provided by the present invention is able to reduce a mask process, which economizes both the fabrication cost and the process time.

The pixel structure formed by the above-described method is shown in FIG. 5G and FIG. 6, where the first gate 430, the first source 452 and the first drain 454 constitute a switch transistor Ts as shown in FIG. 6. The first gate 430 of the switch transistor Ts is electrically connected to the scan line 432, while the first source 452 of the switch transistor Ts is electrically connected to the data line 455. The second gate 434, second source 456 and the second drain 458 constitute a driving transistor Td as shown in FIG. 6. The second gate 434 of the driving transistor Td is electrically connected to the first drain 454. In an embodiment, a capacitor 490 can be further formed in the pixel structure, wherein an end of the capacitor 490 is electrically connected to the first drain 454 and the second gate 434, while another end thereof is electrically connected to the second source 456. One terminal of the capacitor 490 and the second source 456 are electrically connected to a reference voltage 65.

In addition, the cathode 459, the organic functional layer 470 and the anode 472 constitute an organic electroluminescent device 480. In particular, the cathode 459 of the organic electroluminescent device 480 is electrically connected to the second drain 458, while the anode 472 is electrically connected to a power supply 60. In this way, the organic electroluminescent device 480 is not affected by a variation of the voltage V_{gs} between gate and source of the driving transistor Td, which is able to solve the problem of reduced light-emitting luminance caused by a dropped voltage V_{gs} faced by the conventional organic electroluminescent device.

In summary, in the method for fabricating pixel structures of an OELD, since the cathode of the organic electroluminescent device is defined simultaneously with forming the sources and the drains of the driving transistor and the switch component. Therefore, in comparison with the conventional method, the fabrication method provided by the present invention is able to reduce a mask process, which simplifies the fabrication flowchart and shortens the process time, so to effectively advance the throughput. In addition, since the cathode of the organic electroluminescent device is electrically connected to the drain of the driving transistor and the anode thereof is electrically connected to the power supply, hence, the organic electroluminescent device is not affected by a variation of the voltage V_{gs} between gate and source of the driving transistor, which is able to solve the problem of reduced light-emitting luminance caused by a dropped voltage V_{gs} faced by the conventional organic electroluminescent device.

It will be apparent to those skilled in the art that various modifications and variations can be made to the structure of the present invention without departing from the scope or spirit of the invention. In view of the foregoing, it is intended that the specification and examples to be considered as exemplary only, with a true scope and spirit of the invention being indicated by the following claims and their equivalents.

What is claimed is:

1. A method for fabricating a pixel structure of an organic electroluminescent display (OELD), comprising:
forming a first gate, a scan line electrically connected to the first gate and a second gate on a substrate;
forming a gate insulation layer over the substrate to cover the first gate, the scan line and the second gate;
forming a first channel layer and a second channel layer on the gate insulation layer, located over the first gate and the second gate, respectively;
forming a metal layer over the substrate to cover the first channel layer and the second channel layer;
patterning the metal layer to form a first source and a first drain beside the first channel layer and a data line electrically connected to the first source, and simultaneously to form a second source and a second drain beside the second channel layer and a cathode electrically connected to the second drain;
forming an organic functional layer on the cathode; and
forming an anode on the organic functional layer.

2. The method for fabricating pixel structures of an OELD as recited in claim 1, further comprising forming a capacitor, wherein an end of the capacitor is electrically connected to the second gate and the first drain, while another end thereof is electrically connected to the second source.

3. The method for fabricating pixel structures of an OELD as recited in claim 1, further comprising forming a first ohmic contact layer between the first channel layer and both the first source and the first drain.

4. The method for fabricating pixel structures of an OELD as recited in claim 1, further comprising forming a second ohmic contact layer between the second channel layer and both the second source and the second drain.

5. The method for fabricating pixel structures of an OELD as recited in claim 1, wherein the material of the first channel layer and the second channel layer comprises amorphous silicon.

6. The method for fabricating pixel structures of an OELD as recited in claim 1, wherein the material of the first channel layer and the second channel layer comprises organic semiconductor material.

7. The method for fabricating pixel structures of an OELD as recited in claim 1, wherein the material of the cathode comprises aluminum, chromium, silver, aluminum alloy, chromium alloy or silver alloy.

8. The method for fabricating pixel structures of an OELD as recited in claim 1, wherein the material of the anode comprises indium tin oxide, indium zinc oxide or aluminum zinc oxide.

9. The method for fabricating pixel structures of an OBLD as recited in claim 1, wherein, prior to forming the organic emitting layer on the cathode, the method further comprises forming an insulation layer over the substrate to expose the cathode.

10. The method for fabricating pixel structures of an OELD as recited in claim 1, wherein, after forming the cathode, the method further comprises performing a plasma processing on the surface of the cathode.

11. The method for fabricating pixel structures of an OELD as recited in claim 10, wherein the gas used by the plasma processing comprises hydrogen gas, oxygen gas or nitrogen gas.

12. A method for fabricating a pixel structure of an OELD, comprising:
forming a first polysilicon layer and a second polysilicon layer on a substrate;
forming a gate insulation layer over the substrate to cover the first polysilicon layer and the second polysilicon layer;
forming a first gate, a scan line electrically connected to the first gate and a second gate on the gate insulation layer, wherein the first gate and the second gate are located over the first polysilicon layer and the second polysilicon layer, respectively;
forming a first source region and a first drain region in the first polysilicon layer beside the first gate and forming a second source region and a second drain region in the second polysilicon layer beside the second gate;
forming a dielectric layer over the substrate to cover the first gate and the second gate;
forming a first via hole, a second via hole, a third via hole and a fourth via hole in the dielectric layer and the gate insulation layer, wherein the first via hole and the second via hole expose the first source region and the first drain region, respectively; the third via hole and the fourth via hole expose the second source region and the second drain region, respectively;
forming a metal layer on the dielectric layer to fill in the first via hole, the second via hole, the third via hole and the fourth via hole, respectively;
patterning the metal layer to form a first source, a first drain and a data line electrically connected to the first source and to form a second source, a second drain and a cathode electrically connected to the second drain;
forming a protection layer over the substrate to cover the data line, the scan line, the first source, the first drain, the second source and the second drain;
forming an organic functional layer on the cathode; and
forming an anode on the organic functional layer.

13. The method for fabricating pixel structures of an OELD as recited in claim 12, further comprising forming a capacitor, wherein an end of the capacitor is electrically connected to the second gate and the first drain, while another end thereof is electrically connected to the second source.

14. The method for fabricating pixel structures of an OELD as recited in claim 12, wherein the material of the cathode comprises aluminum, chromium, silver, aluminum alloy, chromium alloy or silver alloy.

15. The method for fabricating pixel structures of an OELD as recited in claim 12, wherein the material of the anode comprises indium tin oxide, indium zinc oxide or aluminum zinc oxide.

16. The method for fabricating pixel structures of an OELD as recited in claim 12, wherein, prior to forming the organic emitting layer on the cathode, the method further comprises forming an insulation layer over the substrate to expose the cathode.

17. The method for fabricating pixel structures of an OELD as recited in claim 12, wherein, after forming the cathode, the method further comprises performing a plasma processing on the surface of the cathode.

18. The method for fabricating pixel structures of an OELD as recited in claim 17, wherein the gas used by the plasma processing comprises hydrogen gas, oxygen gas or nitrogen gas.
